(19) United States
(12) Patent Application Publication
(10) Pub. No.: US 2026/0101728 A1
(43) Pub. Date: Apr. 9, 2026

(54) WAFER PROCESSING METHOD

(71) Applicant: DISCO CORPORATION, Tokyo (JP)

(72) Inventors: Akira Mizutani, Tokyo (JP); Hayato Iga, Tokyo (JP)

(21) Appl. No.: 19/331,765

(22) Filed: Sep. 17, 2025

(30) Foreign Application Priority Data
Oct. 4, 2024 (JP) 2024-175028

(51) Int. Cl. H01L 21/02; B23K 26/53; H01L 21/304; H01L 21/67

(52) U.S. Cl. CPC H10P 90/123; B23K 26/53; H10P 52/00; H10P 72/0428; H10P 90/128

(57) ABSTRACT

A wafer processing method for removing a chamfered portion of a first wafer that includes producing a provisionally bonded wafer in which first and second wafers are weakly bonded; forming a ring-shaped modified layer by applying a laser beam to an inner side adjacent to a chamfered portion formed at an outer periphery of the first wafer of the provisionally bonded wafer, and detaching the chamfered portion from the second wafer, with the modified layer serving as a starting point; and producing a completely strongly bonded wafer by annealing the provisionally bonded wafer. The wafer processing method further includes grinding and thinning the first wafer, with the second wafer being held on a chuck table constituting a grinding apparatus, and removing the chamfered portion of the first wafer that is detached from the second wafer, with the modified layer serving as a starting point.

### BACKGROUND

### 1. Technical Field

The present disclosure relates to a wafer processing method for bonding a first wafer and a second wafer and processing the first wafer.

### 2. Description of the Related Art

A wafer having multiple devices such as ICs and LSIs, which are formed on a surface thereof and defined by division lines, is ground at a back surface thereof to have a predetermined thickness. The wafer is then divided into individual device chips by using a dicing apparatus and a laser processing apparatus so as to be used in electrical devices such as mobile phones and personal computers.

Also, a wafer has at an outer periphery thereof a chamfered portion. This chamfered portion is formed into a sharp knife edge when the back surface of the wafer is ground. This may cause a problem in that a crack is formed from the knife edge to the inner side, damaging a device formed near the central region, and a problem in that the chamfered portion that has been formed into a knife edge hurts an operator, for example. As such, a technique for removing the chamfered portion from the wafer has been proposed (see, for example, JP 2020-088187 A).

### SUMMARY

However, the technique in which a first wafer and a second wafer are bonded to form a bonded wafer so as to improve device functionality, and then the back surface of the first wafer is ground has a problem in that removing the chamfered portion from the first wafer is relatively difficult.

That is, the following problems arise.
(1) A wafer bonded by siloxane bonding or the like has a strong bonding force. Even if a laser beam having a wavelength that is transmittable through the first wafer is applied at a focal point located on the inner side adjacent to the chamfered portion so as to form a modified layer inside the first wafer, it is difficult, by this approach alone, to satisfactorily remove the chamfered portion.
(2) When a modified layer is formed as (1) described above to remove the chamfered portion of the first wafer, with the first and second wafers having high mutual adhesion, the effect of the laser beam used to form the modified layer may reach and damage the second wafer.
(3) When a cutting blade is used to remove the chamfered portion from the first wafer, it is difficult to completely remove the same without scratching the second wafer.

In view of the foregoing facts, a main technical issue of the present disclosure is to provide a wafer processing method capable of appropriately removing a chamfered portion of a first wafer when the first wafer and a second wafer are bonded and the first wafer is processed.

To solve the above-mentioned main technical issue, according to the present disclosure, a wafer processing method for bonding a first wafer and a second wafer and processing the first wafer is provided. The wafer processing method includes: producing a provisionally bonded wafer in which a first wafer and a second wafer are provisionally bonded with a relatively weak bonding force; forming a ring-shaped modified layer by applying a laser beam to an inner side adjacent to a chamfered portion formed at an outer periphery of the first wafer of the provisionally bonded wafer, and detaching the chamfered portion from the second wafer, with the modified layer serving as a starting point; and producing a completely bonded wafer with an increased bonding force obtained by annealing the provisionally bonded wafer. The wafer processing method further includes, after the forming the modified layer or after the producing the completely bonded wafer, grinding and thinning the first wafer, with the second wafer being held on a chuck table constituting a grinding apparatus, and removing the chamfered portion of the first wafer that is detached from the second wafer, with the modified layer serving as a starting point.

The forming the modified layer preferably includes forming a radial modified layer extending outward from the ring-shaped modified layer. Also, the method preferably includes, after the producing the provisionally bonded wafer, facilitating chamfered portion detachment by supplying a fluid including at least one of water, water vapor, or mist to an interface of the chamfered portion, at which the first wafer and the second wafer are bonded, so that the fluid enters a region where the chamfered portion can be removed so as to weaken a bonding force. Furthermore, the facilitating chamfered portion detachment preferably includes applying an external force to the interface when supplying the fluid to the interface.

After the producing the provisionally bonded wafer, pre-grinding is preferably performed, before the forming the modified layer, to grind the first wafer so as to remove a layer that interferes with a laser beam that is applied in the forming the modified layer. The first wafer and the second wafer are preferably silicon wafers. In the provisionally bonded wafer, Si and Si are preferably bonded via OH, and in the completely bonded wafer, Si and Si are preferably bonded via O.

A wafer processing method of the present disclosure is a wafer processing method for bonding a first wafer and a second wafer and processing the first wafer, and includes: producing a provisionally bonded wafer in which a first wafer and a second wafer are provisionally bonded with a relatively weak bonding force; forming a ring-shaped modified layer by applying a laser beam to an inner side adjacent to a chamfered portion formed at an outer periphery of the first wafer of the provisionally bonded wafer, and detaching the chamfered portion from the second wafer with the modified layer as a starting point; and producing a completely bonded wafer with an increased bonding force by annealing the provisionally bonded wafer. The wafer processing method includes, after the forming the modified layer or after the producing the completely bonded wafer, grinding and thinning the first wafer with the second wafer held on a chuck table constituting a grinding apparatus, and removing the chamfered portion of the first wafer that is detached from the second wafer with the modified layer as a starting point. This allows the chamfered portion of the first wafer detached from the second wafer to be easily removed, thereby solving the problem described above in (1). Also, when the modified layer is formed after producing the provisionally bonded wafer, the lower adhesion and detachment between the first and second wafers block the laser beam. Thus, the problem of the second wafer being damaged when the modified layer is formed is avoided, thereby solving also the problem described above in (2). Furthermore, the embodiment described above eliminates the need to use a cutting blade to remove the chamfered portion of the first wafer, thereby solving the problem described above in (3).

### BRIEF DESCRIPTION OF THE DRAWINGS

FIG. 1 is a perspective view showing an implementation mode of producing a provisionally bonded wafer of a present embodiment;

FIG. 2 is a perspective view showing a mode in which the provisionally bonded wafer transported to a laser processing apparatus is held on a chuck table;

FIG. 3 is a perspective view showing an implementation mode of forming a modified layer;

FIG. 4A is a partially enlarged cross-sectional view showing a mode of forming a first modified layer, and FIG. 4B is a partially enlarged cross-sectional view showing a mode of forming second modified layers;

FIG. 5 is a plan view of a first wafer in which radial modified layers are formed;

FIG. 6 is a schematic side view showing an implementation mode of facilitating chamfered portion detachment;

FIG. 7 is a perspective view showing an implementation mode of grinding;

FIG. 8A is a perspective view showing one implementation mode of producing a completely bonded wafer, and FIG. 8B is a perspective view showing another implementation mode of producing a completely bonded wafer.

### DESCRIPTION OF THE PREFERRED EMBODIMENTS

Hereinafter, an embodiment of a wafer processing method according to the present disclosure will be described in detail with reference to the accompanying drawings.

The present disclosure provides a wafer processing method capable of appropriately removing a chamfered portion of a first wafer when the first wafer and a second wafer are bonded and the first wafer is processed. The method includes the procedures described below.

### Producing provisionally Bonded Wafer

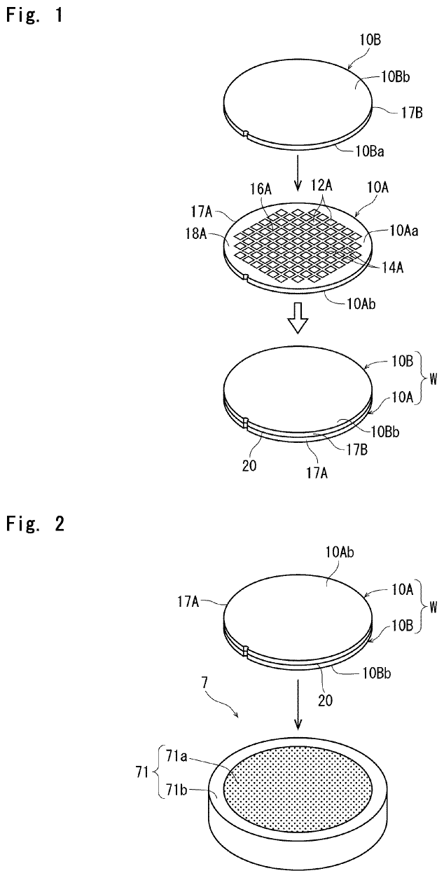

FIG. 1 shows an implementation mode of producing a provisionally bonded wafer in the present embodiment. To perform producing of a provisionally bonded wafer of this embodiment, a first wafer 10A and a second wafer 10B as shown in the drawing are prepared. The first wafer 10A may be a silicon (Si) wafer having a diameter of 300 mm and a thickness of 300 μm, for example, and includes multiple devices 12A, which are formed on a surface 10Aa and defined by division lines 14A. The first wafer 10A has the surface 10Aa and a back surface 10Ab, and includes a central effective region 16A, in which the devices 12A to be used as products are formed, and an outer peripheral surplus region 18A, which includes a chamfered portion 17A at its outer periphery and surrounds the effective region 16A. The second wafer 10B, which has a similar configuration to the first wafer 10A, is a silicon (Si) wafer that includes a chamfered portion 17B at its outer periphery and an effective region (not shown), in which multiple devices are formed and defined by division lines on a surface 10Ba facing downward as viewed in the drawing.

To perform producing of a provisionally bonded wafer of this embodiment, the surface 10Aa of the first wafer 10A, which is made of silicon (Si) as described above, and the surface 10Ba of the second wafer 10B, which is made of silicon (Si), are treated to be hydrophilic and then bonded together by pressure bonding. As a result, hydrogen bonds are formed between the hydrogen atoms (H) of the hydroxyl groups (OH groups) formed at the surface 10Aa of the first wafer 10A and the oxygen atoms (O) of the hydroxyl groups (OH groups) formed at the surface 10Ba of the second wafer 10B. Also, the hydrogen atoms (H) of the hydroxyl groups (OH groups) formed at the surface 10Ba of the second wafer 10B are hydrogen bonded with the oxygen atoms (O) of the hydroxyl groups (OH groups) formed at the surface 10Aa of the first wafer 10A, forming an interface 20 by Si—OH—OH—Si bonding. This produces a provisionally bonded wafer W, which is bonded integrally. The above-mentioned bonding via OH has a weaker bonding force than a completely bonded wafer, which will be described below, and in this embodiment, this is referred to as provisional bonding.

Once the provisionally bonded wafer W is produced as described above, forming of a modified layer, which is described below, is performed. Here, when the back surface 10Ab of the first wafer 10A after producing the provisionally bonded wafer W has unevenness that interferes with the laser beam applied in forming a modified layer, or when it is covered with a film (such as an oxide film) that does not allow the applied laser beam to pass through and causes problems such as diffused reflection, pre-grinding, which is described below, is performed to remove the layer with unevenness or film.

### Pre-Grinding

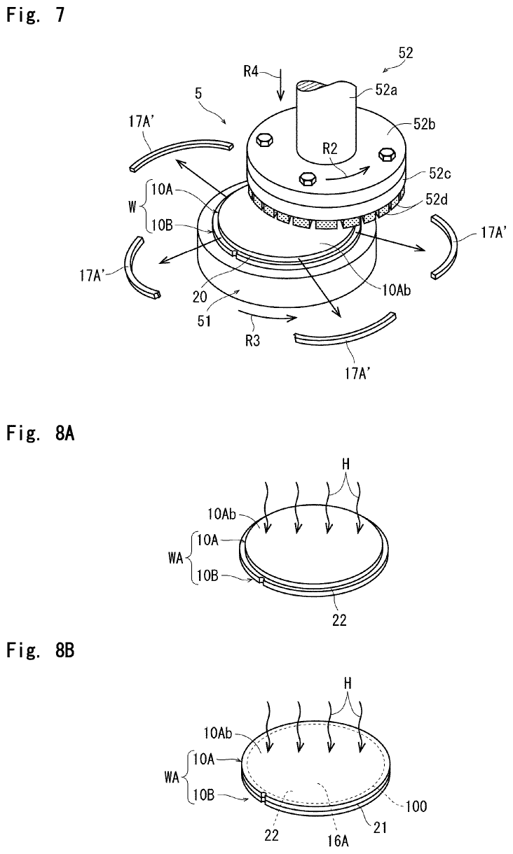

When performing the above-mentioned pre-grinding, the provisionally bonded wafer W is transported, for example, to a grinding apparatus 5 (see FIG. 7, only a portion of which is shown) described below, and the first wafer 10A is placed facing upward on a chuck table 51 and held by suction. The back surface 10Ab of the first wafer 10A is ground by a grinding unit 52 of the grinding apparatus 5 while supplying grinding water onto the back surface 10Ab of the first wafer 10A using a grinding water supply unit (not shown) and while measuring the thickness of the bonded wafer W using a contact or non-contact measuring gauge (not shown). As described above, this grinding is a grinding process performed to remove any layer formed on the back surface 10Ab of the first wafer 10A that has unevenness or a film that may interfere with a laser beam. This grinding is completed when a grinding process is performed to an extent that removes the layer. This allows an appropriate modified layer to be formed without causing diffused reflection when a laser beam is applied from the back surface 10Ab of the first wafer 10A in forming the modified layer, which is described below. When the back surface 10Ab of the first wafer 10A does not have any unevenness or a film that may interfere with the laser beam LB, the above pre-grinding is omitted.

### Forming Modified Layer

Once producing the provisionally bonded wafer as described above and the pre-grinding, which is performed if necessary, have been completed, forming of a modified layer is performed in which a laser beam is applied to the inner side adjacent to the chamfered portion 17A formed at the outer periphery of the first wafer 10A of the provisionally bonded wafer W to form a ring-shaped modified layer, and the chamfered portion 17A is detached from the second wafer 10B with the modified layer as a starting point.

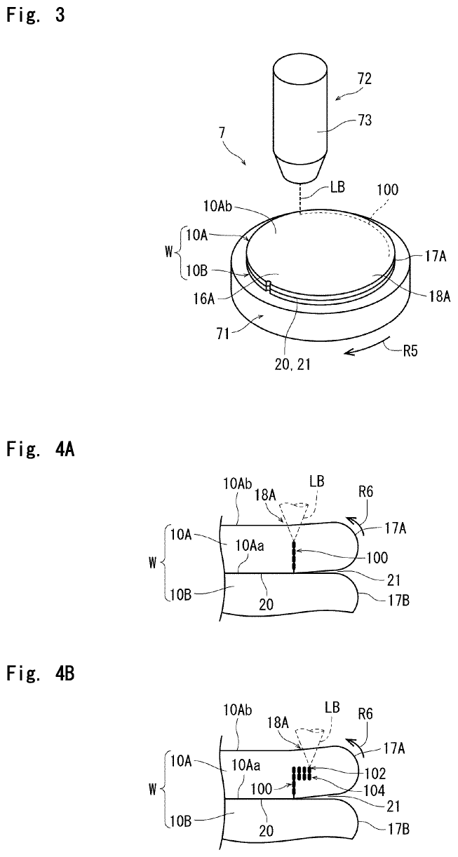

To perform forming of the modified layer of this embodiment, the provisionally bonded wafer W is transported to a laser processing apparatus 7 (only a part of which is shown) shown in FIGS. 2 and 3. The laser processing apparatus 7 at least includes a chuck table 71, which holds the provisionally bonded wafer W by suction, and a laser beam applying unit 72, which includes a condenser 73 that focuses and applies a laser beam LB having a wavelength transmittable through the first wafer 10A.

Once the provisionally bonded wafer W is transported to the laser processing apparatus 7, as shown in FIG. 2, the provisionally bonded wafer W is placed on a holding surface 71a of the chuck table 71 with the first wafer 10A facing upward. The provisionally bonded wafer W is then suction-held by operating a suction unit (not shown) connected through a frame 71b surrounding the holding surface 71a. Then, alignment is performed on the provisionally bonded wafer W held by suction on the chuck table 71 using an alignment unit (not shown). This alignment detects the outer periphery position where the chamfered portion 17A of the first wafer 10A is formed, the center position of the first wafer 10A, and the height of the back surface 10Ab of the first wafer 10A so as to detect a processing position to which the focal point of the laser beam LB is positioned to apply the laser beam LB on the inner side adjacent to the chamfered portion 17A formed at the outer periphery of the first wafer 10A (for example, a position at a radius of 147 mm from the center point of the first wafer 10A).

Forming of the modified layer according to the present disclosure may include a first step and a second step described below, for example.

### First Step

Based on the position information of the processing position detected by the above-mentioned alignment, the chuck table 71 is moved to place the processing position, which is set at the outer periphery of the first wafer 10A of the provisionally bonded wafer W, directly below the condenser 73 of the laser beam applying unit 72 as shown in FIG. 3. Then, as can be understood by referring to FIG. 4A in addition to FIG. 3, the laser beam LB is applied from the side corresponding to the back surface 10Ab of the first wafer 10A with its focal point positioned inside the processing position of the first wafer 10A, and the chuck table 71 is rotated in the direction indicated by arrow R5 in FIG. 3 to form a ring-shaped first modified layer 100 along the inner side of the chamfered portion 17A of the first wafer 10A.

The first modified layer 100 formed in the first step of this embodiment is preferably formed by multiple layers in the up-down direction, as shown in FIG. 4A. For example, the first modified layer 100 shown in FIG. 4A is formed by four modified layers arranged in the up-down direction. To form the first modified layer 100 including such multiple layers, first, the focal point of the laser beam LB is positioned at a position set in the deepest part (for example, a depth of 180 μm from the back surface 10Ab) near the interface 20 inside the inner side adjacent to the chamfered portion 17A of the first wafer 10A, and the laser beam LB is applied while rotating the chuck table 71 in the direction indicated by arrow R5 described above, to form a ring-shaped modified layer of the first layer along the chamfered portion 17A. Then, while rotating the chuck table 71, the focal point is raised three times toward the back surface 10Ab (upward) such that the depth from the back surface 10Ab is shifted to 170 μm, to 160 μm, and then to 150 μm, thereby forming a total of four ring-shaped modified layers in the up-down direction along the chamfered portion 17A. In this manner, the laser beam LB is applied with its focal point positioned near the interface 20 so as to form the first modified layer 100 at a relatively deep position in the first wafer 10A. This forms a crack along the first modified layer 100 on the side of the first wafer 10A corresponding to the surface 10Aa, that is, at a position reaching the interface 20. By forming the ring-shaped first modified layer 100 in this manner, the chamfered portion 17A is warped and detached from the chamfered portion 17B of the second wafer 10B in the direction indicated by arrow R6 with the first modified layer 100 as a starting point, thereby forming a minute gap 21.

The first modified layer 100 shown in FIG. 4A is conceptually illustrated, and the depth positions of the layers are not in accordance with the actual dimensions. The first step is completed as above. The first modified layer 100 formed by the first step is not limited to being formed of four layers, and an appropriate number of layers may be set depending on the wavelength and output of the laser beam LB applied by the laser beam applying unit 72, the thickness of the first wafer 10A, the material of the first wafer 10A, and the like.

### Second Step

After the first modified layer 100 is formed by the first step described above, the second step may be performed to form a second modified layer on the outer or inner side of the first modified layer 100 at a relatively shallow position that does not reach the interface 20 of the bonded wafer W. As shown in FIG. 4B, the second step of the present embodiment forms ring-shaped second modified layers 102 and 104 by applying the laser beam LB with its focal point positioned at positions that are adjacent to the uppermost modified layer of the first modified layer 100 (modified layer formed at a depth of 150 μm from the back surface 10Ab) and the modified layer formed below it (at a depth of 160 μm from the back surface 10Ab) on the outer side of these layers and by rotating the chuck table 71. As shown, the second modified layers 102 and 104 are each formed of multiple modified layers (three in the illustrated embodiment) that are adjacent in the radial direction and formed at the same depth.

In forming the modified layer as described above, in addition to forming the first modified layer 100 in the first step, the second step forms the second modified layers 102 and 104 adjacent to the first modified layer 100 at relatively shallow depth positions that do not reach the interface 20. This allows a greater external force to be applied to form the gap 21 by detaching the chamfered portion 17A from the interface 20 in the direction indicated by arrow R6 shown in FIG. 4B with the first modified layer 100 as the starting point. As a result, the bonding force of the interface 20 can be more reliably reduced, so that the gap 21 described above is more reliably formed. Additionally, the crack originating from the first modified layer 100 can be further extended.

The forming of the modified layer of this embodiment is completed as described above. In the above embodiment, the second modified layers 102 and 104 are formed on the outer side of and adjacent to the first modified layer 100. However, the present disclosure is not limited to this, and they may be formed on the inner side of and adjacent to the first modified layer 100. In this case, as with the case of forming them on the outer side described above, an external force is applied to warp the chamfered portion 17A in the direction indicated by arrow R6 with the first modified layer 100 as a starting point, thereby reliably detaching the chamfered portion 17A of the first wafer 10A from the second wafer 10B.

When forming the second modified layers in the second step described above, there is no limitation to forming three ring-shaped modified layers as described above, and two or less, or four or more layers may be formed.

The laser processing conditions used in forming the modified layer may be set to the following laser processing conditions 1 or 2, for example.

### Laser Processing Conditions 1

Wavelength: 1099 nm
Repetition frequency: 80 kHz
Average output: 2.0 W
Processing feed rate: 450 mm/s
or

### Laser Processing Conditions 2

Wavelength: 1342 nm
Repetition frequency: 90 kHz
Average output: 1.9 W
Processing feed rate: 400 mm/s

When the above-mentioned first and second steps are performed under the above laser processing conditions 2, it is preferable to set the depth positions for forming the modified layers to positions slightly deeper than the depth positions of the modified layer 100 and modified layers 102 and 104 described above. For example, to perform the first step, the focal point of the laser beam LB is positioned at a position set at a depth of 183 μm from the back surface 10Ab near the interface 20 inside the inner side adjacent to the chamfered portion 17A of the first wafer 10A, and the laser beam LB is applied while rotating the chuck table 71 to form a ring-shaped modified layer of the first layer along the chamfered portion 17A. Then, while rotating the chuck table 71, the focal point is raised three times toward the back surface 10Ab (upward) such that the depth from the back surface 10Ab is shifted to 173 μm, to 163 μm, and then to 153 μm, thereby forming a total of four ring-shaped modified layers along the chamfered portion 17A. Furthermore, when the modified layers 102 and 104 are formed by performing the second step, their depths may match the depths of the third and fourth layers, that is, at a depth of 163 μm and a depth of 153 μm from the back surface 10Ab.

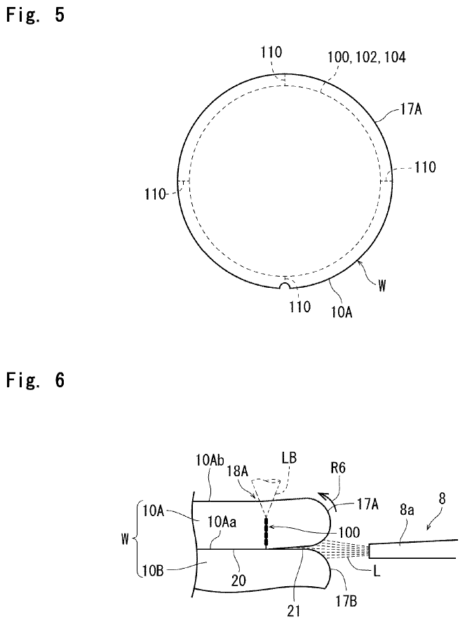

As shown in FIG. 5, forming the modified layer as described above may form radial modified layers 110 that extend from a region inside the first wafer 10A in which the first modified layer 100 is formed to the outer side where the chamfered portion 17A is formed, for example. The illustrated radial modified layers 110 may be formed, for example, by applying a laser beam LB under laser processing conditions similar to those used to form the first modified layer 100 described above. The radial modified layers 110 may be formed at multiple locations (four locations in the illustrated embodiment) at equal intervals along the outer periphery of the first wafer 10A. By forming these radial modified layers 110, the ring-shaped chamfered portion 17A is detached into multiple broken pieces 17A′ when the chamfered portion 17A is removed from the first wafer 10A by grinding, which will be described below, allowing the chamfered portion 17A to be removed in a desirable manner.

Facilitating Chamfered Portion Detachment In this embodiment, after producing a provisionally bonded wafer, facilitating chamfered portion detachment may be performed before forming the modified layer described above, simultaneously with forming the modified layer, or after forming the modified layer, for example. Facilitating chamfered portion detachment is supplying a fluid L, which includes water, water vapor, or mist, to the interface 20 between the chamfered portion 17A and the chamfered portion 17B of the bonded first and second wafers 10A and 10B so that the fluid L enters a region where the chamfered portion 17A can be removed to weaken the bonding force.

When facilitating chamfered portion detachment is performed, this can be performed by providing a fluid supply unit 8 shown in FIG. 6 in the laser processing apparatus 7, for example. As shown in the drawing, the fluid supply unit 8 of this embodiment includes a nozzle 8a and is connected to a fluid supply source (not shown) that supplies a fluid L to the nozzle 8a. The fluid supply unit 8 is configured such that the height of the nozzle 8a and the distance from the provisionally bonded wafer W can be adjusted by a driving unit (not shown), the nozzle 8a can be positioned at a desired position, and the fluid L can be supplied horizontally from the tip of the nozzle 8a as shown in the drawing.

When facilitating chamfered portion detachment is performed simultaneously with forming the modified layer, as shown in FIG. 6, the tip of the nozzle 8a of the fluid supply unit 8 is brought close to the provisionally bonded wafer W on which forming of the modified layer is being performed, and positioned at the height of the interface 20, at which the chamfered portion 17A of the first wafer 10A and the chamfered portion 17B of the second wafer 10B are bonded.

Then, a fluid L that weakens the bonding force of the interface 20 is supplied to the interface 20 from the tip of the nozzle 8a. By supplying the fluid L to the region at the interface 20 where the chamfered portion 17A of the first wafer 10A is removed, that is, the region where the gap 21 described above is formed, the bonding force of the interface 20 is weakened, allowing the gap 21 to be favorably formed in forming the modified layer. The fluid L supplied from the nozzle 8a is not limited to pure water in liquid form, and may be water vapor or mist. Furthermore, facilitating chamfered portion detachment is not limited to being performed simultaneously with forming the modified layer, and may be performed before forming the modified layer, or after forming the modified layer and before grinding described below.

In this embodiment, the fluid L is supplied from the nozzle 8a of the fluid supply unit 8. This also acts as an external force that warps the chamfered portion 17A of the first wafer 10A away from the chamfered portion 17B of the second wafer 10B in the direction indicated by arrow R6 in FIG. 6. In other words, the fluid supply unit 8 weakens the bonding force of the interface 20 through the entry of the fluid L. This decreased bonding force of the interface 20 reduces the adhesion between the chamfered portion 17A of the first wafer 10A and the second wafer 10B, thereby facilitating detachment and further reliably forming the gap 21 described above.

### Grinding

After forming the modified layer as described above, the provisionally bonded wafer W is transported to a grinding apparatus 5 (only a portion of which is shown) shown in FIG. 7 to grind and thin the back surface 10Ab of the first wafer 10A, and also to remove the chamfered portion 17A of the first wafer 10A, which is detached from the second wafer 10B, with the modified layer 100 as a starting point.

The grinding apparatus 5 includes at least a chuck table 51 and a grinding unit 52 shown in FIG. 7. As shown in FIG. 7, the grinding unit 52 is a unit for grinding the back surface 10Ab of the first wafer 10A of the provisionally bonded wafer W held by suction on the chuck table 51, and includes a rotating spindle 52a, which is rotated by a rotation drive mechanism (not shown), a wheel mount 52b, which is attached to the lower end of the rotating spindle 52a, and a grinding wheel 52c attached to the lower surface of the wheel mount 52b. The lower surface of the grinding wheel 52c includes multiple grindstones 52d arranged in a ring shape.

Once the provisionally bonded wafer W on which forming of the modified layer has been performed is transported to the grinding apparatus 5, the provisionally bonded wafer W is placed on the chuck table 51 of the grinding apparatus 5 with the first wafer 10A facing upward and the second wafer 10B facing downward, and the suction unit (not shown) is activated to hold the provisionally bonded wafer W by suction.

Then, the rotating spindle 52a of the grinding unit 52 is rotated in the direction indicated by arrow R2 in FIG. 7 at 6000 rpm, for example, while the chuck table 51 is rotated in the direction indicated by arrow R3 at 300 rpm, for example. Then, while grinding water is supplied onto the back surface 10Ab of the first wafer 10A by a grinding water supply unit (not shown), a grinding feed unit (not shown) is operated to bring the grindstones 52d into contact with the back surface 10Ab of the first wafer 10A, and the grinding wheel 52c is fed downward to grind as indicated by arrow R4 at a grinding feed rate of 0.1 μm/sec, for example. At this time, the grinding is performed while measuring the thickness of the bonded wafer W with a contact or non-contact measuring gauge (not shown), so that the wafer can be thinned to a desired thickness.

Although not shown in the drawings, the grinding described above can be performed in two steps. For example, the above-mentioned grinding apparatus 5 may include a grinding unit that includes a rough grinding wheel having coarse grindstones for rough grinding, and a grinding unit that includes a finish grinding wheel having fine grindstones for finish grinding. Rough grinding, in which the back surface 10Ab of the first wafer 10A is roughly ground with the rough grinding wheel, and finish grinding, in which the back surface 10Ab is finish-ground with the finish grinding wheel, may be performed successively.

By performing the above-mentioned grinding, as shown in FIG. 7, the first wafer 10A of the provisionally bonded wafer W is thinned, and the grinding unit 52 applies an external force to the first wafer 10A to remove the chamfered portion 17A, thereby removing the chamfered portion 17A as broken pieces 17A′ with the modified layer 100 as a starting point as described above. In this embodiment, the first and second wafers 10A and 10B are bonded together using OH, which has a relatively weak bonding force compared to siloxane bonding, to form the provisionally bonded wafer W. As such, the chamfered portion 17A is removed from the first wafer 10A in a desirable manner with the modified layer 100 as a starting point. Furthermore, in this embodiment, forming of the modified layer also forms radial modified layers 110. As such, when the chamfered portion 17A is removed from the first wafer 10A in the grinding described above, the chamfered portion 17A is detached into multiple broken pieces 17A′ with the radial modified layers 110 as starting points, allowing the chamfered portion 17A to be removed in a desirable manner.

Producing Completely Bonded Wafer After the chamfered portion 17A of the first wafer 10A is removed by the grinding described above, the producing a completely bonded wafer is performed to produce a completely bonded wafer WA, in which the bonding force is increased by annealing the provisionally bonded wafer W, as shown in FIG. 8A.

As shown in FIG. 8A, to convert the above-described provisionally bonded wafer W into a completely bonded wafer WA, annealing is performed in which the first and second wafers 10A and 10B are pressed together, placed in a chamber (not shown) including a heater (not shown) that applies far-infrared rays H, for example, and heated to about 300° C., for example. As a result, water (H₂O) is removed from the OH groups formed at the bonding surface of the provisionally bonded wafer W, forming covalent bonds (siloxane bonds) in which Si and Si are bonded via oxygen atoms (O). Accordingly, a new interface 22 with high bonding strength is formed between the surface 10Aa of the first wafer 10A and the surface 10Ba of the second wafer 10B, thereby producing a completely bonded wafer WA in which the first and second wafers 10A and 10B are bonded with a large bonding force. This completes producing the completely bonded wafer.

In the above embodiment, producing the completely bonded wafer is performed on the provisionally bonded wafer W that has been subjected to grinding and from which the chamfered portion 17A is removed. However, the present disclosure is not limited to this, and producing the completely bonded wafer may be performed at an appropriate timing before performing the above grinding. For example, as shown in FIG. 8B, after forming the modified layer and before performing the grinding to remove the chamfered portion 17A, annealing may be performed in which the first and second wafers 10A and 10B are pressed together, placed in a chamber (not shown) including a heater (not shown) that applies far-infrared rays H, for example, and heated to about 300° C., for example. As a result, in the same manner as described above, water (H₂O) is removed from the OH groups formed at the bonding surface of the provisionally bonded wafer W, forming covalent bonds (siloxane bonds) in which Si and Si are bonded via oxygen atoms (O). Accordingly, a new interface 22 with high bonding strength is formed between the surface 10Aa of the first wafer 10A and the surface 10Ba of the second wafer 10B, thereby producing a completely bonded wafer WA. The gap 21 is already formed by detaching the chamfered portion 17A of the first wafer 10A from the second wafer 10B in forming the modified layer even before the grinding is performed to remove the chamfered portion 17A. Thus, a new interface 22 is formed between the effective region 16A of the first wafer 10A and the device region (not shown) of the second wafer 10B by covalent bonding (siloxane bonding) in which Si and Si are bonded via oxygen (O), thereby increasing the bonding force. In the subsequent grinding, the chamfered portion 17A detached from the second wafer 10B is removed in a desirable manner. When producing the completely bonded wafer is performed before the grinding as described above, it is preferable to perform facilitating the chamfered portion detachment described above before or during the grinding.

According to the above embodiment, performing the grinding facilitates the removal of the chamfered portion 17A of the first wafer 10A that is detached from the second wafer 10B, thereby solving the problem described above in (1). Also, when the modified layer is formed at the stage of producing the provisionally bonded wafer W, the lower adhesion and detachment between the first and second wafers 10A and 10B block the laser beam. Thus, the problem of the second wafer 10B being damaged when the modified layer is formed is avoided, thereby solving also the problem described above in (2). Furthermore, the embodiment described above eliminates the need to use a cutting blade to remove the chamfered portion 17A, thereby solving the problem described above in (3).

### REFERENCE SIGNS LIST

5 Grinding apparatus
51 Chuck table
52 Grinding unit
52a Rotating spindle
52b Wheel mount
52c Grinding wheel
52d Grindstone
7 Laser processing apparatus
71 Chuck table
72 Laser beam applying unit
73 Condenser
8 Fluid supply unit
8a Nozzle
10A First wafer
10Aa Surface
10Ab Back surface
12A Device
14A Division line
16A Effective region
17A Chamfered portion
18A Outer peripheral surplus region
10B Second wafer
10Ba Surface
10Bb Back surface
20 Interface
21 Bonding force decreased region
21′ Gap
100 First modified layer
102, 104 Second modified layer
110 Radial modified layer
L Fluid (pure water)
W Bonded wafer

What is claimed is:

1. A wafer processing method for bonding a first wafer and a second wafer and processing the first wafer, the wafer processing method comprising:
producing a provisionally bonded wafer in which a first wafer and a second wafer are provisionally bonded with a relatively weak bonding force;
forming a ring-shaped modified layer by applying a laser beam to an inner side adjacent to a chamfered portion formed at an outer periphery of the first wafer of the provisionally bonded wafer, and detaching the chamfered portion from the second wafer, with the modified layer serving as a starting point; and
producing a completely bonded wafer with an increased bonding force obtained by annealing the provisionally bonded wafer,
the wafer processing method further comprising, after the forming the modified layer or after the producing the completely bonded wafer, grinding and thinning the first wafer, with the second wafer being held on a chuck table constituting a grinding apparatus, and removing the chamfered portion of the first wafer that is detached from the second wafer, with the modified layer serving as a starting point.

2. The wafer processing method of claim 1, wherein the forming the modified layer includes forming a radial modified layer extending outward from the ring-shaped modified layer.

3. The wafer processing method of claim 1, further comprising, after the producing the provisionally bonded wafer, facilitating chamfered portion detachment by supplying a fluid including at least one of water, water vapor, or mist to an interface of the chamfered portion, at which the first wafer and the second wafer are bonded, so that the fluid enters a region where the chamfered portion can be removed so as to weaken a bonding force.

4. The wafer processing method of claim 3, wherein the facilitating chamfered portion detachment includes applying an external force to the interface when supplying the fluid to the interface.

5. The wafer processing method of claim 1, wherein after the producing the provisionally bonded wafer and before the forming the modified layer, pre-grinding is performed to grind the first wafer so as to remove a layer that interferes with a laser beam that is applied in the forming the modified layer.

6. The wafer processing method of claim 1, wherein
the first wafer and the second wafer are silicon wafers,
in the provisionally bonded wafer, Si and Si are bonded via OH, and
in the completely bonded wafer, Si and Si are bonded via O.
